(19) United States
(12) Patent Application Publication
(10) Pub. No.: US 2011/0189836 A1
(43) Pub. Date: Aug. 4, 2011

(54) ION/IOFF IN SEMICONDUCTOR DEVICES BY UTILIZING THE BODY EFFECT

(75) Inventors: Yuan-Peng Chao, Hsinchu (TW); Yao Wen Chang, Hsinchu (TW); Hsing Wen Chang, Miaoli (TW); Che-Shih Lin, Hsinchu (TW)

(73) Assignee: MACRONIX INTERNATIONAL CO., LTD., Hsinchu (TW)

(21) Appl. No.: 12/699,977

(22) Filed: Feb. 4, 2010

(51) Int. Cl. H01L 21/326

(52) U.S. Cl. 438/466; 257/E21.327

(57) ABSTRACT

A method for reducing leakage current of a semiconductor device includes supplying a substantially constant and non-zero bulk bias to a relatively low threshold voltage semiconductor device during formation of a conductive channel of the semiconductor device and during the formation of a non-conductive channel of the semiconductor device.

### BACKGROUND

1. Technical Field

The present invention relates to semiconductor devices, and more particularly, to a short-channel semiconductor device having improved subthreshold voltage swing and reduced leakage current.

2. Related Art

In conventional MOS technologies, the gate electrode should be formed with the same impurity doping as the impurity doping type of the source and drain regions. Over concerns of manufacturing costs, buried channel MOS are invented, which consist of a gate electrode with a different type of implant from the channel. Due to the depletion region that results from the n-type polysilicon gate electrode and the p-type doped channel at the channel surface, holes are mainly located at an area deeper from the surface. Accordingly, this structure is commonly referred to as a buried channel PMOS device.

However, performance of the buried-channel PMOS device is problematic since its subthreshold swing would degrade significantly with scaling and there would exist a large drain leakage current under high Vd operations. Accordingly, a method is required to reduce the subthreshold swing and suppress the drain leakage current under high drain voltage.

FIG. 1 includes a schematic circuit diagram and operational characteristics diagram of a buried-channel PMOS device. In FIG. 1, as the channel length of the buried-channel PMOS device 1 is scaled, poor subthreshold characteristics are exhibited. Accordingly, the threshold voltage Vt of the PMOS device 1 should be set high enough to limit the OFF current I_{OFF} within a desired range. However, the increased threshold voltage Vt does not favor low-voltage operational design and increases subthreshold swing. A small subthreshold swing is highly desired since it improves the ratio between the ON- and OFF-currents. However, as shown in FIG. 1, the buried channel PMOS device 1 exhibits significantly worse subthreshold swing, as well as very high leakage current at gate voltages of ˜0V.

Thus, reduction of subthreshold swing and suppression of the drain leakage current under high drain voltage is needed.

### SUMMARY

Short-channel semiconductor devices and related methods are described herein.

In one aspect, a method for reducing leakage current of a semiconductor device includes supplying a substantially constant and non-zero bulk bias to a relatively low threshold voltage semiconductor device during formation of a conductive channel of the semiconductor device and during the formation of a non-conductive channel of the semiconductor device. In another aspect, along with the supplied bulk bias, by choosing a short channel buried channel PMOS device with a smaller threshold voltage, the ON-current would even be better than a same type device with a higher threshold voltage which is without the bulk bias supplied at the same leakage level.

A method for reducing leakage current of complementary semiconductor devices interconnected between the voltage source and ground includes supplying a substantially constant bulk bias to a first semiconductor device during formation of a conductive channel and formation of a non-conductive channel of the first semiconductor device, and supplying a substantially constant bulk bias to a second semiconductor device during formation of a non-conductive channel of the second semiconductor device and during formation of a non-conductive channel of the second semiconductor device, the first semiconductor device being different from the second semiconductor device, wherein the leakage current of the first semiconductor device between the source and drain is substantially the same as the leakage current of the second semiconductor device between the source and drain, and the threshold voltage of the first semiconductor device is lower than the threshold voltage of the second semiconductor device.

In another aspect, a method for reducing leakage current of a semiconductor device includes supplying a substantially constant and non-zero bulk bias to one of a buried-channel device and a surface-channel device during formation of a conductive channel of the semiconductor device, and supplying the substantially constant and non-zero bulk bias to the one of the buried-channel device and a surface-channel device during formation of a non-conduction channel of the semiconductor device, wherein the step of supplying the substantially constant and non-zero bulk bias changes the threshold voltage of the one of the buried-channel device and a surface-channel device, and the threshold voltage of the first semiconductor device is lower than the threshold voltage of the second semiconductor device.

These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIG. 1 includes a schematic circuit diagram and operational characteristics diagram of a buried channel PMOS device;

FIG. 2A is an operational characteristic diagram of low-Vt and high-Vt PMOS test devices having different threshold voltages Vt according to the present embodiment;

FIG. 2B is an operational characteristic diagram of the low-Vt PMOS test device receiving a bulk bias according to the present embodiment;

FIG. 3A is an operational characteristic diagram of low-Vt and high-Vt PMOS test devices having similar OFF currents I_{OFF} according to the present embodiment;

FIG. 3B is an operational characteristic diagram of low-Vt and high-Vt PMOS test devices with the low-Vt PMOS test device having a lower threshold voltage Vt according to the present embodiment;

FIG. 4A is an operational characteristic diagram of the low-Vt and high-Vt PMOS test devices having similar OFF currents I_{OFF} according to the present embodiment;

FIG. 4B is an operational characteristic diagram of low-Vt and high-Vt PMOS test devices with the low-Vt PMOS test device having an improved ON current I_{ON} according to the present embodiment; and

FIG. 5 is a schematic circuit diagram and timing diagram of an exemplary circuit for reducing leakage current according to another embodiment.

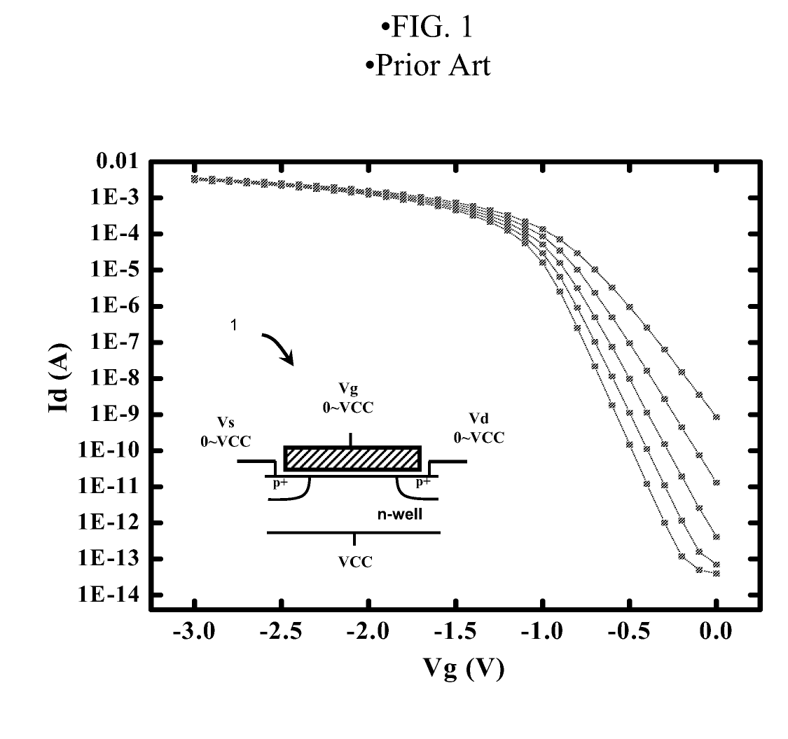

### DETAILED DESCRIPTION

For purposes of exemplary descriptions, a PMOS device is explained below. However, the benefits and advantages of the present invention are equally applicable to an NMOS device. Moreover, the benefits and advantages are more broadly applicable to buried-channel semiconductor devices, both NMOS and/or PMOS, and surface-channel semiconductor devices, both NMOS and/or PMOS.

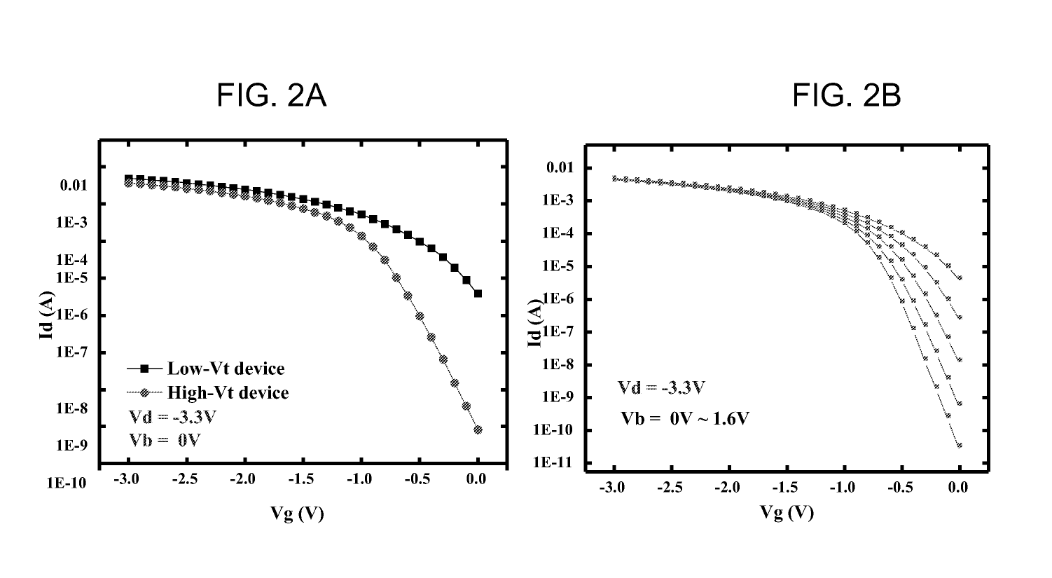

FIG. 2A is an operational characteristic diagram of low-Vt and high-Vt buried-channel PMOS test devices having different threshold voltages Vt according to the present embodiment, and FIG. 2B is an operational characteristic diagram of the low-Vt buried-channel PMOS test device receiving a bulk bias according to the present embodiment. In FIG. 2A, the high-Vt buried-channel PMOS device has poor subthreshold swing and has to have a relatively larger threshold voltage Vt (˜850 mV) to keep an acceptable OFF-current. However, its high threshold voltage is not favorable for low-voltage operation. As to the low-Vt buried-channel PMOS device, its subthreshold swing is worse and has a relatively larger OFF-current I_{OFF}. However, as shown in FIG. 2B, by applying a bulk bias (0V˜1.6V) to the low-Vt device (i.e., a device with a threshold voltage of about 600 mV), the subthreshold swing can be improved and leakage current of the low-Vt device can be effectively suppressed. Thus, use of the low-Vt device is preferred in order to both improve the subthreshold swing and suppress the leakage current as compared to the high-Vt device.

In FIGS. 2A and 2B, the low-Vt and the high-Vt devices are buried-channel PMOS devices, each having an n-type polysilicon gate electrode and a p-type doped channel.

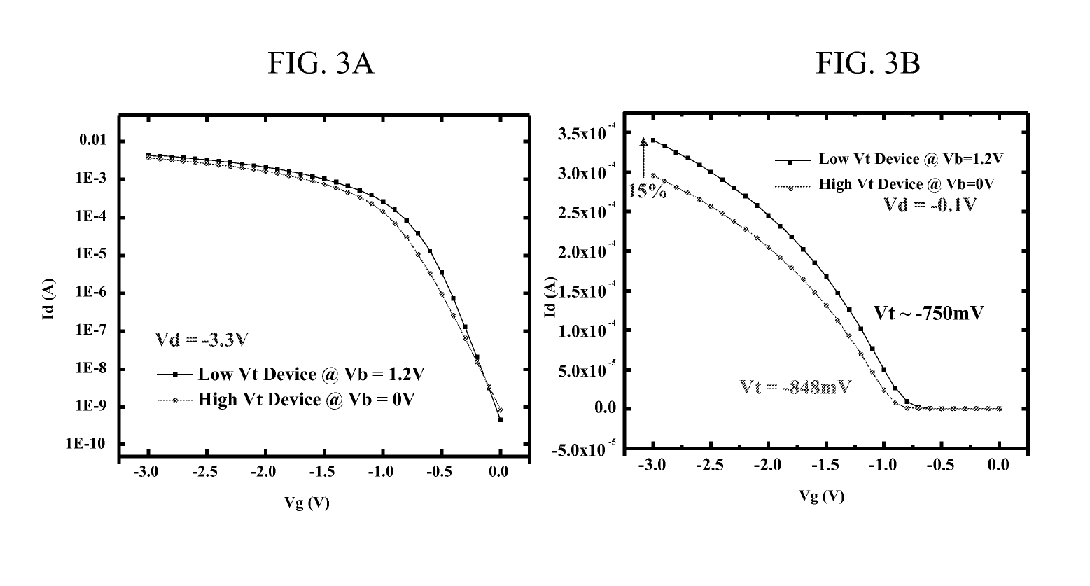

FIG. 3A is an operational characteristic diagram of the low-Vt PMOS with some body effect and the high-Vt PMOS test devices. Both devices have similar OFF currents I_{OFF} according to the present embodiment, and FIG. 3B is an operational characteristic diagram of the low-Vt PMOS with some body effect and the high-Vt PMOS test devices. In FIG. 3A, by applying a relatively small positive bulk bias Vb to the low-Vt device during both its operational and standby states, the leakage current can be reduced to substantially the same level as the high-Vt device. As a result, as shown in FIG. 3B, the low-Vt PMOS with some body effect has lower Vt than the high-Vt PMOS. For example, as compared to FIG. 2A, the threshold voltage Vt of the low-Vt device is increased from about −600 mV to about −750 mV. At the same time, by supplying the bulk bias to the low-Vt device, the leakage current can be lowered to substantially the same level as the high-Vt device and the threshold voltage Vt of the low-Vt device is still lower.

In FIGS. 3A and 3B, the low-Vt device and the high-Vt device are buried-channel PMOS devices, each having an n-type polysilicon gate electrode and a p-type doped channel.

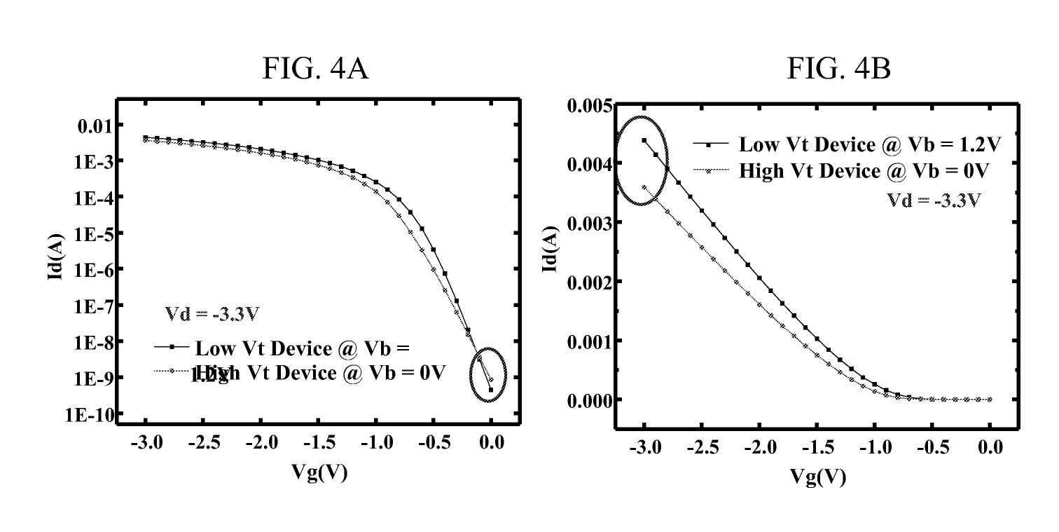

FIG. 4A is an operational characteristic diagram of the low-Vt PMOS device with some body effect and the high-Vt PMOS test device having similar OFF currents I_{OFF} according to the present embodiment, and FIG. 4B is an operational characteristic diagram of the low-Vt and the high-Vt PMOS test devices with the low-Vt PMOS test device having an improved ON current I_{ON} according to the present embodiment. In FIG. 4A, by applying a relatively small positive bulk bias Vb to the low-Vt device during both the operational and standby states, the leakage current of the low-Vt device can be reduced to substantially the same level as the high-Vt device. As result, as shown in FIG. 4B, the ON current I_{ON} of the low-Vt device can be improved.

In FIGS. 4A and 4B, the low-Vt test device and the high-Vt test device are buried-channel PMOS devices, each having an n-type polysilicon gate electrode and a p-type doped channel.

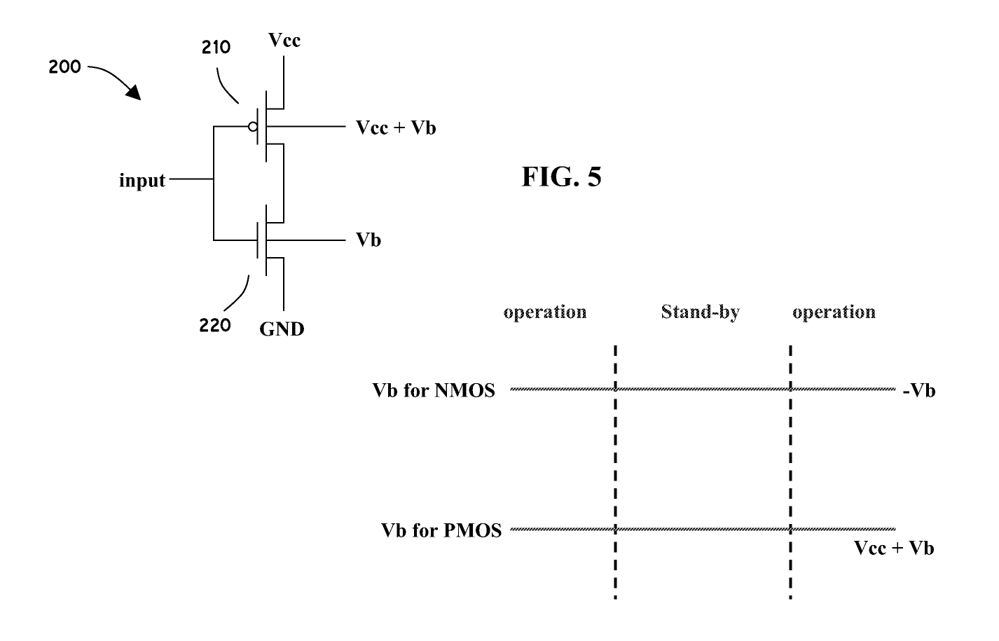

FIG. 5 is a schematic circuit diagram and timing diagram of an exemplary circuit for reducing leakage current according to another embodiment. In FIG. 5, the circuit 200 includes a PMOS device 210 and an NMOS device 220, each receiving a different, substantially constant bulk bias. For example, the PMOS device 210 receives a substantially constant bulk bias V_{CC}+Vb and the NMOS device 220 receives a substantially constant bulk bias Vb. Although the bulk bias applied to NMOS and PMOS devices may be different from each other, they are still “constant” with regard to time-scale. Here, the bulk bias Vb is received as a reverse bias to the NMOS device 220 of the circuit 200 during operational and standby states, i.e., during formation of a conductive channel and formation of a non-conductive channel, in order to reduce the leakage current from V_{CC} to GND. Accordingly, as detailed with reference to FIGS. 2A-4B, application of the bulk bias V_{CC}+Vb to the PMOS device 210, also during both the operational and standby states, can effectively suppress the leakage current of the PMOS device 210, as well as lower the threshold voltage Vt of the PMOS device 210 and improve the ON current I_{ON} of the PMOS device 210 compared with the embodiment of using high-Vt devices. Thus, the operational speed of the circuit 200 would not be impaired. In FIG. 6, the PMOS device 210 can include one of a buried-channel and a surface-channel PMOS device having an n-type polysilicon gate electrode and a p-type doped channel. In addition, the NMOS device 220 can include one of a buried-channel and a surface-channel NMOS device.

As shown in FIGS. 3B and 4B, for example, the subthreshold swing is significantly reduced by supplying a bulk bias to the MOS device. For example, FIGS. 3B and 4B demonstrate that the reduced subthreshold swing improves the ratio between the ON-currents and OFF-currents of the MOS device.

According to the present invention, an NMOS device may have a relatively smaller threshold voltage Vt of about +0.3V˜+0.7V, and a PMOS device may have a relatively smaller threshold voltage Vt of about −0.3V˜−0.7V. Accordingly, after a body effect of about +0.5V˜+1.5V is applied to the NMOS device, or after a body effect of about −0.5V˜−1.5V is applied to the PMOS device, which are suitable for circuit operation, the degraded subthreshold swing can be improved at the same time. For example, improved ON-current (Ion) can be as high as about 20%. In addition, both the NMOS and PMOS devices can include buried-channel and surface-channel devices.

According to the present invention, a device having a relatively lower threshold voltage can be used for a device having a relatively higher threshold voltage even when a bulk bias voltage is applied. Accordingly, although a bulk bias voltage is supplied, using a lower threshold voltage device provides for reduced leakage current and a lower threshold voltage comparable to that of the higher threshold voltage device. In addition, subthreshold swing of the lower threshold voltage device is improved by application of the bulk bias voltage.

While certain embodiments of the inventions have been described above, it will be understood that the embodiments described are by way of example only. Accordingly, the inventions should not be limited based on the described embodiments. Rather, the scope of the inventions described herein should only be limited in light of the claims that follow when taken in conjunction with the above description and accompanying drawings.

What is claimed is:

1. A method for reducing leakage current of a semiconductor device, comprising:
supplying a substantially constant and non-zero bulk bias to a low threshold voltage semiconductor device during formation of a conductive channel of the semiconductor device and during formation of a non-conductive channel of the semiconductor device.

2. The method according to claim 1, further comprising supplying the substantially constant and non-zero bulk bias to the semiconductor device during formation of a non-conduction channel of the semiconductor device.

3. The method according to claim 1, wherein the step of supplying the substantially constant and non-zero bulk bias changes the threshold voltage of the semiconductor device.

4. The method according to claim 1, wherein the step of supplying the substantially constant and non-zero bulk bias lowers leakage current of the semiconductor device and improves subthreshold swing.

5. The method according to claim 1, wherein the semiconductor device is one of a buried-channel semiconductor device and a surface-channel semiconductor device, and the step of supplying the substantially constant and non-zero bulk bias changes the threshold voltage of the device.

6. The method according to claim 5, wherein the semiconductor device is a PMOS device and includes an n-type polysilicon gate electrode and a p-type doped channel.

7. The method according to claim 5, wherein the semiconductor device is a NMOS device.

8. The method according to claim 5, wherein a ratio between ON-current and OFF-current of the semiconductor device is improved.

9. A method for reducing leakage current of complementary semiconductor devices interconnected between source and drain, comprising:
supplying a substantially constant bulk bias to a first semiconductor device during formation of a conductive channel and formation of a non-conductive channel of the first semiconductor device; and
supplying a substantially constant bulk bias to a second semiconductor device during formation of a non-conductive channel of the second semiconductor device and formation of a non-conductive channel of the semiconductor device, the first semiconductor device being different from the second semiconductor device.

10. The method according to claim 9, wherein the supplying the constant bulk bias to the first semiconductor device lowers leakage current of the first semiconductor device and improves subthreshold swing.

11. The method according to claim 9, wherein the first semiconductor device is one of a buried-channel device and a surface-channel device, and the step of supplying the bulk bias changes the threshold voltage of the first semiconductor device.

12. The method according to claim 11, wherein the first semiconductor device is a PMOS device, and includes an n-type polysilicon gate electrode and a p-type doped channel.

13. The method according to claim 9, wherein the second semiconductor device is one of a buried-channel device and a surface-channel device, and the step of supplying the bulk bias changes the threshold voltage of the second semiconductor device.

14. The method according to claim 13, wherein the second semiconductor device is an NMOS device.

15. The method according to claim 9, wherein a ratio between ON-current and OFF-current of the first semiconductor device and of the second semiconductor device is improved.

16. A method for reducing leakage current of a semiconductor device, comprising:
supplying a substantially constant and non-zero bulk bias to one of a buried-channel device and a surface-channel device during formation of a conductive channel of the semiconductor device; and
supplying the substantially constant and non-zero bulk bias to the one of the buried-channel device and a surface-channel device during formation of a non-conduction channel of the semiconductor device,
wherein the step of supplying the substantially constant and non-zero bulk bias changes the threshold voltage of the one of the buried-channel device and a surface-channel device.
